(19) United States
(12) Patent Application Publication
(10) Pub. No.: US 2010/0252744 A1
(43) Pub. Date: Oct. 7, 2010

(54) RADIATION DETECTOR WITH A PLURALITY OF ELECTRODE SYSTEMS

(75) Inventors: Christoph HERRMANN, Aachen (DE); Klaus Juergen ENGEL, Aachen (DE); Christian BAEUMER, Hergenrath (BE)

Correspondence Address: PHILIPS INTELLECTUAL PROPERTY & STANDARDS, P. O. Box 3001, BRIARCLIFF MANOR, NY, 10510, US

(73) Assignee: KONINKLIJKE PHILIPS ELECTRONICS N.V., EINDHOVEN (NL)

(21) Appl. No.: 12/730,277

(22) Filed: Mar. 24, 2010

(30) Foreign Application Priority Data
Apr. 6, 2009 (EP) 09157356.8

(51) Int. Cl. G01T 1/24; G01T 7/00; H01L 21/28

(52) U.S. Cl. 250/370.14; 438/80; 257/E21.158

(57) ABSTRACT

The invention relates to a radiation detector that comprises a converter element and a plurality of electrode systems arranged on said element, wherein each electrode system comprises a primary electrode and a supplementary electrode, which are connected to a readout circuitry. The primary and the supplementary electrodes may particularly be realized by planar, parallel stripes extending in a common plane, wherein said stripes are electrically connected above said plane.

### CROSS REFERENCE TO RELATED APPLICATIONS

This application claims the benefit of European provisional application serial no. 09157356.8 filed Apr. 6, 2009, which is incorporated herein by reference.

### FIELD OF THE INVENTION

The invention relates to a radiation detector comprising a converter element for converting incident radiation into electrical signals and with electrodes disposed on said converter element. Moreover, it relates to an examination apparatus comprising such a radiation detector and to a method for the production of such a radiation detector.

### BACKGROUND OF THE INVENTION

Radiation detectors for high-energy radiation like X-rays or γ-rays are for example needed in imaging apparatuses like CT (Computed Tomography) scanners. For these applications, approaches based on photon-counting Spectral CT have been described in literature that offer a large potential of new possibilities (Roessl, Proska: “K-edge imaging in x-ray computed tomography using multi-bin photon counting detectors”, Phys. Med. Biol. 52 (2007) 4679-4696). However, such approaches pose high demands on the accuracy and resolution of the applied radiation detectors.

### SUMMARY OF THE INVENTION

Based on this situation it was an object of the present invention to provide a radiation detector that is particularly suited for an application in Spectral CT and that provides a high accuracy in photon-counting applications.

This object is achieved by a radiation detector according to claims 1, 13 and 14, a method according to claim 2, and an examination apparatus according to claim 15. Preferred embodiments are disclosed in the dependent claims.

According to its first aspect, the invention relates to a “first” radiation detector for the detection of incident (electromagnetic) radiation, particularly of high-energy radiation like X-rays or γ-rays. The radiation detector comprises the following components:

a) A converter element for converting incident radiation into electrical signals. The converter element may be made from any suitable direct conversion material that transforms incident radiation to be detected into electrical signals, particularly into a pulse of electrical charges (e.g. electron-hole pairs in the conduction resp. valence band of the material).
b) A plurality of electrode systems that are arranged on the aforementioned converter element. Typically, each of said electrode systems is located in some associated compact region, wherein these regions with the electrode systems are distributed in a regular manner (e.g. a grid or matrix pattern) over one side of the converter element. The electrode systems are further defined by the feature that each of them comprises a first electrode, called “primary electrode” in the following, and a separate second electrode, called “supplementary electrode” in the following. The primary and supplementary electrodes may be identical or similar in design or not. They differ however in the way they are used during the operation of the radiation detector, which is the reason why different names have been assigned to them. Also for this reason the primary and the supplementary electrode will below sometimes be considered as being “complementary” to each other. Moreover, it should be noted that these electrodes need not necessarily have a compact, connected geometry; in fact, it is even preferred that they consist of a plurality of sub-units as will be explained below in connection with preferred embodiments of the invention.
c) A readout circuitry that is individually connected to each of the aforementioned primary electrodes and supplementary electrodes of the electrode systems. The readout circuitry comprises (analog and/or digital) electronic components for applying electrical potentials to the connected primary and supplementary electrodes. As its name indicates, the readout circuitry will further be capable to detect secondary electrical signals that are generated in these electrodes by the above mentioned electrical signals which are generated in the converter element. In a typical example, the secondary electrical signals are charges or charge-displacements caused in an electrode by a pulse of electrical charges in the converter element.

The described radiation detector has the advantage that it allows to evaluate electrical signals generated in the converter element by incident radiation with the help of a plurality of electrode systems. Depending on the arrangement of the electrode systems, a spatial resolution (if the electrode systems are arranged perpendicularly to the radiation incidence) and/or a spectral resolution (if the electrode systems are arranged in line with the radiation incidence) can be realized. In the first case, the radiation detector has a design that is known as “pixelated”, wherein the pixels correspond to different picture elements of projection images generated with the detector.

By using primary and supplementary electrodes in each electrode system, the described radiation detector can considerably improve the accuracy of signal detection. Thus it is particularly possible to reduce the low-energy tail of electrical signals generated in the converter element. This makes the radiation detector particularly apt for an application in photon-counting Spectral CT.

The invention further relates to a method for manufacturing a radiation detector, particularly a radiation detector of the kind described above. The method comprises the following steps:

a) Disposing a plurality of electrode systems on a converter element such that each electrode system comprises a primary electrode and, electrically isolated therefrom, a supplementary electrode.
b) Individually connecting a readout circuitry to the primary electrodes and the supplementary electrodes.

The method comprises in general form steps that lead to a radiation detector of the kind described above. Therefore, reference is made to the preceding description for more information on the details, advantages and improvements of that method.

In the following, various preferred embodiments of the invention are described that relate to both the radiation detector and the manufacturing method defined above. It should be noted in this context that, if some feature will be explained for “at least one” electrode system, primary electrode and/or supplementary electrode, it is usually preferred that this feature is realized for all electrode systems, primary electrodes and/or supplementary electrodes.

According to a first optional embodiment, the primary electrode and the supplementary electrode of at least one electrode system are arranged in a common planar layer with a thickness of less than e.g. about 10 μm, preferably less than about 5 μnm. Said common planar layer may particularly be located in contact to the surface of the converter element on which the electrodes are disposed. Arranging a primary and a supplementary electrode in a common thin layer guarantees that both of them have similar access to and can similarly interact with the material of the converter element.

As was already mentioned, the electrode systems are preferably arranged in a (regular or irregular) one-dimensional or two-dimensional pattern on one side of the converter element. In case of a two-dimensional pattern, electrode systems can be arranged both perpendicularly and parallel to the radiation incidence, thus allowing both spatial and spectral resolution of said radiation.

Particularly preferred is an embodiment in which the electrode systems are arranged on the converter element in a hexagonal two-dimensional pattern. This means that the area covered by each electrode system is hexagonal and that all these hexagonal areas are regularly arranged in a honeycomb pattern. As the ratio between length of the border and inner area is in a hexagon smaller than in a rectangle/square, border artifacts like charge sharing between neighboring pixels are reduced in a hexagonal arrangement. Moreover, this arrangement has a higher isotropy (i.e. rotational symmetry) than e.g. rectangular tessellations.

The primary and supplementary electrodes can be realized in a large variety of geometrical shapes. According to one particular embodiment, at least one primary electrode and/or at least one supplementary electrode comprises a plurality of parallel stripes. Preferably, these stripes are identical or similar in length and width and are homogenously distributed in a rectangular region.

According to a further development of the aforementioned embodiment, both the primary electrode and the supplementary electrode of at least one electrode system comprises such parallel stripes, wherein the stripes of the primary electrode and of the supplementary electrode are arranged in an alternating manner.

In the aforementioned electrode geometry of parallel stripes, the type of an electrode (primary or supplementary) does not change within the area of the electrode system in the direction of the stripes, while it repetitively alters in a direction perpendicular thereto.

According to another embodiment of the invention, a design with a higher isotropy is achieved by providing at least one electrode system within which the primary electrode and/or the supplementary electrode is at least once interrupted in any arbitrary direction within the electrode system area. Most preferably, there is an alternation of primary electrode and supplementary electrode in any arbitrary direction within the electrode system area. Such an electrode system can be achieved by an appropriate distribution of (small, compact) sub-units constituting the primary electrode or the supplementary electrode, respectively. Said appropriate distribution may for example comprise a random distribution, or the arrangement of equilateral triangles in a hexagonal pattern. Still another example is a chessboard pattern of square sub-units isolated from each other (the black fields constituting the primary and the white fields units constituting the supplementary electrode).

According to another possible geometry of the electrodes, at least one primary electrode and/or at least one supplementary electrode comprises an electrode area with a plurality of holes. The electrode area may for example have a chessboard geometry with a grid of squares (black fields) that overlap at their corners and that encircle holes (white fields). The complementary electrode may then be disposed in said holes.

In a particularly preferred embodiment of the invention, at least one primary electrode and/or at least one supplementary electrode consists of a plurality of sub-units that are arranged in a common plane, which is usually defined by the surface of the converter element, on which the electrode is arranged. The stripes that were mentioned above are one example of such sub-units constituting an electrode.

The aforementioned sub-units of the primary or the supplementary electrode will usually be short-circuited (i.e. electrically coupled). To this end, it is preferred that each sub-unit carries a contact terminal which is disposed above the common plane in which the sub-units are arranged. In this context, the term “above” corresponds to that side of the common plane which is opposite to the side where the converter element is arranged. In other words, the converter element is considered as lying “below” the common plane. One particular example of the aforementioned contact terminals are bump balls on the sub-units. Such bump balls can for example be used to directly couple a readout circuitry to the electrode systems on the converter element. Another particular example of contact terminals are vias (i.e. electrically conductive passages) that are embedded in an isolating layer which covers the sub-units.

The sub-units that constitute a primary or a supplementary electrode are, in a preferred embodiment, electrically coupled to each other by a connection element which extends some distance away from the common plane of the sub-units. The connection element may for example be a metal line that contacts the aforementioned vias in a plane extending parallel to and at a distance from the common plane of the sub-units. Arranging a connection element in a plane different from the plane of the sub-units has the advantage that this connection does not electrically interfere with the detection function of the sub-units.

According to another particularly preferred embodiment of the invention, an isolating layer is disposed between the converter element and at least one primary electrode and/or at least one supplementary electrode. Such an isolating layer guarantees that no electrical charges can be exchanged between the converter element and the corresponding electrode, but does not limit (desired) interactions via electrical fields.

In another preferred embodiment of the invention, at least one primary electrode and/or at least one supplementary electrode extends along two opposite sides of the associated electrode system. If said electrode is for example realized by parallel stripes, two parallel stripes may be arranged at the two outermost, opposite sides of the associated electrode system. In this way it can be guaranteed that symmetric, definite electrical conditions prevail at the borders of the electrode system.

In the manufacturing method of the radiation detector, the disposition of at least one primary electrode and/or at least one supplementary electrode may optionally comprise the following sub-steps:

a) Disposing a plurality of sub-units in a common plane on the converter element.
b) Disposing at least one contact terminal on each sub-unit.
c) Disposing a connection element on said contact terminals such that the sub- units are electrically coupled.

With this procedure, a radiation detector of the kind described above can be produced. Reference is therefore made to the above description for more details about said method.

According to a second aspect, the invention relates to a “second” radiation detector for the detection of incident (electromagnetic) radiation, particularly of high-energy radiation like X-rays or γ-rays, comprising the following components:

a) A converter element for converting incident radiation into electrical signals.
b) An electrode system that is arranged on the aforementioned converter element and that comprises a “primary electrode” and a separate “supplementary electrode”. Furthermore, the primary electrode comprises an electrode area with at least one hole, preferably with a plurality of holes.
c) A readout circuitry that is individually connected to the aforementioned primary electrode and supplementary electrode of the electrode system.

The electrode area of the primary electrode may, for example, have a chessboard geometry with a grid of squares (black fields) that overlap at their corners and that encircle holes (white fields). The complementary electrode may preferably be disposed in the hole(s), which may for example be achieved by a layer extending (on an intermediate insulating layer) over the whole electrode area of the primary electrode.

A “second” radiation detector according to the second aspect has the advantage that it may be designed with a high symmetry in the plane of the electrode area, thus avoiding any directional bias with respect to the processing of electrical signals. Besides the special geometry of its primary electrode, the radiation detector may else have design features like the radiation detector according to the first aspect of the invention.

According to a third aspect, the invention relates to a “third” radiation detector for the detection of incident (electromagnetic) radiation, particularly of high-energy radiation like X-rays or γ-rays, comprising the following components:

a) A converter element for converting incident radiation into electrical signals.
b) An electrode system that is arranged on the aforementioned converter element and that comprises a “primary electrode” and a separate “supplementary electrode”. Furthermore, the design of the primary electrode and/or of the supplementary electrode shall be such that, in each direction within the area of the electrode system, the primary electrode and/or the supplementary electrode is at least once interrupted. Most preferably, it is multiply interrupted.
c) A readout circuitry that is individually connected to the aforementioned primary electrode and supplementary electrode of the electrode system.

In the “third” radiation detector, no direction within the area of the respective electrode system can be found along which both the primary and the supplementary electrode will extend without interruption. Hence an arrangement can be achieved in which the primary electrode and/or the supplementary electrode is very isotropically distributed across the area of the electrode system, avoiding the occurrence of certain bias directions. In particular, electrical charges that are induced by electrical signals generated in the adjacent converter element are thus more evenly distributed between primary and supplementary electrodes.

In a preferred embodiment of the “third” radiation detector, condition b) is fulfilled for both the primary electrode and the supplementary electrode. This means that each of these electrodes is once or (preferably) multiple times interrupted in any arbitrary direction within the area of the electrode system.

According to another preferred embodiment of the “third” radiation detector, there exists at least one direction in the area of the electrode system in which an interruption section of one electrode (for example the primary electrode) exists with the other electrode (in the example the supplementary electrode) being disposed in said interruption section. This means that, when “traveling” along said direction within the area of the electrode system, primary electrode and supplementary electrode are at least once alternately traversed. Most preferably, such an alternation of primary electrode and supplementary electrode occurs multiple times and/or in each direction within the area of the electrode system. In this case a highly even distribution of induced charges is achieved between the primary and supplementary electrode.

It should be noted that the features of the radiation detectors according to the first, second, and third aspect of the invention may arbitrarily be combined.

Moreover, the invention relates to an examination apparatus for the examination of an object (e.g. a patient) with radiation, said apparatus comprising a (“first”, “second”, or “third”) radiation detector of the kind described above. The examination apparatus may particularly be applied as a baggage inspection apparatus, a material testing apparatus, a material science analysis apparatus, or a medical application apparatus. The examination apparatus may especially be selected from the group consisting of an X-ray apparatus (e.g. a fluoroscopic device), Computed Tomography (CT) imaging system (most preferably a photon-counting Spectral CT imaging system), Coherent Scatter Computed Tomography (CSCT) imaging system, Positron Emission Tomography (PET) imaging system, and Single Photon Emission Computerized Tomography (SPECT) imaging system.

### BRIEF DESCRIPTION OF THE DRAWINGS

These and other aspects of the invention will be apparent from and elucidated with reference to the embodiment(s) described hereinafter. These embodiments will be described by way of example with the help of the accompanying drawings in which:

FIG. 1 shows in a perspective view a radiation detector with an electrode system comprising two coplanar grids;

FIG. 2 shows in a top view a radiation detector like that of FIG. 1 with a readout circuitry attached to the electrode systems;

FIG. 3 shows in a side view a radiation detector with a two-dimensional array of electrode systems;

FIG. 4 shows in a perspective view a radiation detector with a two-dimensional array of electrode systems on one surface;

FIGS. 5 to 9 illustrate consecutive steps of the production of a radiation detector having bond pads in an elevated plane;

FIG. 10 shows a variant of the radiation detector of FIG. 9 with a different placement of the bond pads;

FIG. 11 shows a top view onto an electrode system with a chessboard pattern;

FIG. 12 shows in a side view a radiation detector with a two-dimensional hexagonal array of electrode systems, the electrodes consisting of triangular sub-units;

FIG. 13 shows in a side view a radiation detector with a two-dimensional hexagonal array of electrode systems, the electrodes consisting of full and half-circles.

Like reference numbers or numbers differing by integer multiples of 100 refer in the Figures to identical or similar components.

### DESCRIPTION OF PREFERRED EMBODIMENTS

One trend in modern X-ray imaging systems is the exploitation of spectral information inherently available due to the fact that an X-ray tube emits a polychromatic X-ray spectrum. In the long run, spectral information will become available by energy-resolving photon-counting detectors based on a direct conversion material (e.g. Cd[Zn]Te). Hence, K-edge imaging will be enabled, which is considered to be the most valuable clinical add-on of a CT system with evaluation of spectral information. K-edge imaging will enable important applications like colorectal cleansing (“electronic stool removal”) and provide highly improved separation between calcified plaques and the contrast-agent filled vessel.

Essential for the success of a photon counting detector is a good spectral resolution, which can be degraded by mainly two effects. First, charge sharing between neighbored pixels can trigger a count in each pixel with a shared signal. Without expensive and slow coincidence electronics, the original photon energy cannot be obtained; the spectral response of the detector has a so-called “low-energy tailing”, which means that a certain number of measured photon energies results in a more or less random energy between zero and the original photon energy. Second, electrons are usually by far faster than holes. The electronics is usually adapted to a fast collection of the electrons, but the remaining holes still capacitively induce charges on the collecting anodes, which leads to a broadened photo peak in the spectral response.

To overcome these disadvantages, several concepts can be used. One concept is to use small pixels, for which the “small pixel effect” reduces the area to which the unwished charges of the holes are induced. As a result, the spectral response shows a sharper photo peak, however the low-energy tailing is increased as smaller pixels lead to a larger charge sharing between neighbored pixels. In an improved concept, the anodes may be reduced to an even smaller area being surrounded by negatively charged so-called steering electrodes. On the one hand, the more negatively charged steering electrode directs electrons towards the small anode areas, which well reduces charge sharing between neighbored pixels. On the other hand, the steering electrode takes over a large part of the unwished induced hole charges, such that also the photo peak is sharpened. However, the steering concept suffers from other disadvantages, as a relatively high voltage needs to be applied between steering electrode and anode, which results in high leakage currents and thus an increased noise level.

The aforementioned techniques cannot localize sufficiently enough the weighting potential—thus resulting in a low-energy tail—especially in case of thin detector layers, as they are required to deal with the very high count rates in detector pixels, which face the direct beam or are behind the scanned object close to the direct beam; as a result of a reduced count rate in thin detector layers also pulse pile-up is reduced. For the extended Alvarez-Macovsky decomposition approach (cf. Roessl et al., above) it is very important to reduce the low-energy tail further in order to improve the measurement results of the K-edge component.

It is therefore proposed here to use electrode systems with e.g. coplanar grids for defining the pixelated anodes of a radiation detector in conjunction with readout electronics, which measure the difference between the signals originating from a collecting and a non-collecting electrode (grid). Coplanar grids have been described in literature only in connection with bulk detectors (cf. Luke: “Single-polarity charge sensing in ionization detectors using coplanar electrodes”, Appl Phys Lett 1994; He et al.: “Coplanar grid patterns and their effect on energy resolution of CdZnTe detectors”, NIM A 1998). Coplanar grids consist basically of thin stripes, wherein each second stripe (“even” as well as “odd” stripes) is galvanically connected such that two grids are formed in a comb-like structure. If a voltage (lower than that used for a steering electrode concept) is applied between the two grids, electrons are repulsed from the more negatively charged grid, and collected by the more positively charged grid. The more negatively charged grid is the “non-collecting” grid, while the more positively charged grid is the “collecting grid”. Due to capacitive charge coupling, remaining holes induce charges to both grids. As the two grids, however, offer an almost equal area to the remaining holes, the capacitively induced signal to both grids is almost identical. If the current induced to each of the grids is measured with two different electronic channels, they can be subtracted from each other. As a result, after integration of the difference signal, the pure electron charge signal remains, as the hole-induced charge cancels out.

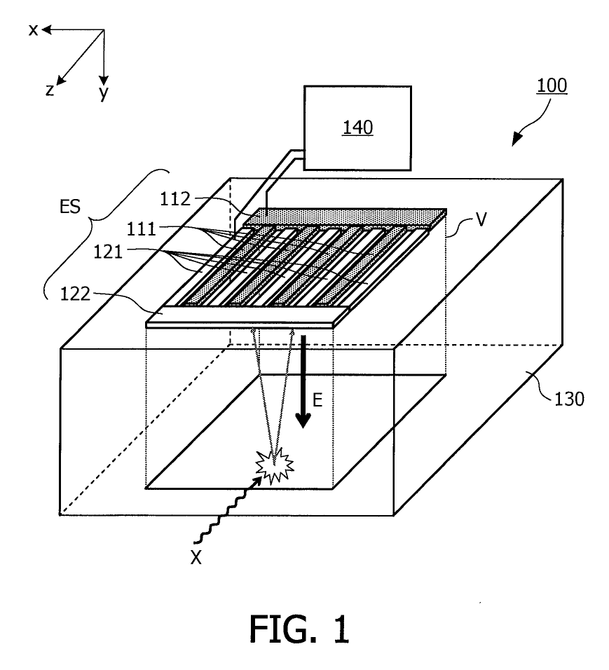

FIG. 1 illustrates this approach for a radiation detector 100 according to a first embodiment of the invention. It should be noted that only one single voxel V is shown in this representation, though the detector has a large number of such voxels V. The radiation detector 100 comprises the following components:

A converter element 130, for example a cuboid block of a direct conversion material like Si, Ge, GaAs, HgI, CZT (cadmium zinc telluride), and/or CdTe, in which incident X-rays X are converted into an electrical signal. The signal will usually consist of charges in the conducting band that can move under the influence of an electrical field. Such an electrical field E is generated in the converter element 130 by the application of different potentials to opposite sides (top and bottom in the Figure) of the converter element.

Electrode systems ES (only one of them is shown) that each consist of two separate electrodes 111, 121. These electrodes will in the following be called “primary electrode” 111 (or “collecting electrode”, with reference to their electron collecting behavior), and “supplementary electrode” 121 (or “non-collecting electrode”).

In the shown example, the primary or collecting electrode consists of a plurality of parallel stripes 111. Similarly, the supplementary or non-collecting electrode consists of a plurality of parallel stripes 121, which are arranged parallel to and alternating with the aforementioned stripes 111 of the primary electrode. The stripes 111 of the primary electrode are electrically connected at one end by a connection element 112; similarly, the stripes 121 of the supplementary electrode are electrically connected at an opposite end by a connection element 122.

During the use of the radiation detector, the primary and supplementary electrodes 111, 121 are (usually) operated as anodes, with the corresponding cathode being disposed on the opposite side of the converter element 130 (bottom side in the Figure).

A readout circuitry 140 that is only schematically indicated in the Figure and that is electrically connected to the primary electrodes and supplementary electrodes.

In the readout circuitry 140, the difference of the signals induced on the collecting and the non-collecting electrodes 111, 121 is read out. The induced signal of any trapped charge (whether negative or positive) therefore disappears in the difference signal. Furthermore, the subtraction entails that only charge, which is very close to the anode side and thus induces charge virtually only on the collecting electrode 111, truly contributes to the measured signal. Under the assumption that only holes are trapped, this approach provides a device, which measures the signal of electrons alone, thus eliminating the adverse influence of the much lower mobility of holes in e.g. Cd[Zn]Te and the resulting higher risk of hole trapping. However, care has to be taken with respect to an increase of the overall noise on the measured pulse, which may occur due to a subtraction of two analog signals with uncorrelated noise.

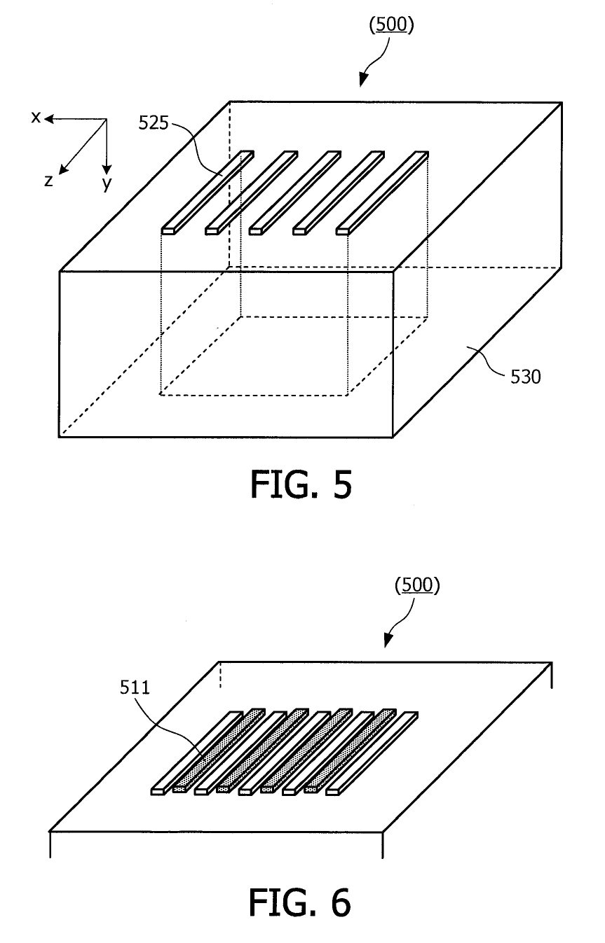

A challenge in realizing a device like that of FIG. 1 is to provide the very small coplanar grid structures of the electrode system ES so that all stripes of the coplanar grid positioned in parallel after each other including the necessary gap do not cover a distance of more than about 1 mm. This constraint is mainly given by the need to keep the detector voxel size defined by the electrode system ES in conjunction with the thickness of the material of the converter element 130 small enough so that the count rates in the detector voxel V are still limited. If several detector layers are devised (as described below with respect to FIG. 4), detector voxel volumes of this size still result in acceptable count rates so that also in the direct beam only voxels of the top detector layer see a count rate, which is so high that saturation occurs (i.e. either the direct conversion material or the readout electronics cannot separate individual pulses, and energy-resolving photon counting is no longer possible).

A straight-forward approach to the above demands is the design of FIG. 1, where the individual stripes 111 of the collecting electrode are connected with a metal connection element 112 already on the converter material, and likewise for the individual stripes 121 of the non-collecting grid.

However, the metal structures 112, 122 connecting the individual stripes 111, 121 to some extent compromise the “ideal” operation, since on these structures also charge is induced. Especially if charge is deposited at the edge of the voxel V above an interconnecting metal structure 112 or 122, the signals induced on the collecting and the non-collecting electrodes are quite different already when the charge is still far away from the anode side, as illustrated in FIG. 1. Hence, charge deposited at the edge of the detector voxel V will cause a non-zero difference signal between collecting and non-collecting electrode, even if the distance from the anode is large, which should be avoided.

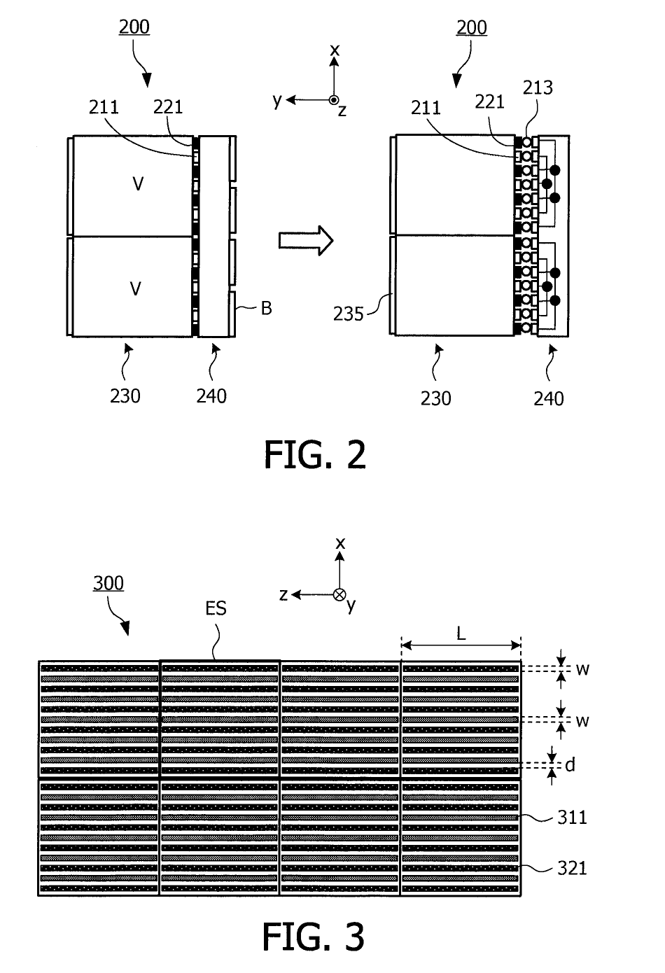

It is therefore proposed here to preferably only deposit individual, parallel stripes on the converter bulk material, and to provide the interconnect via the readout electronics, which have to be bonded to the electrodes anyway. This is shown in more detail in FIG. 2 in a top view onto a radiation detector 200. Two voxels V of a converter material 230 are shown, with the primary electrodes 211 and supplementary electrodes 221 deposited on top of them and cathodes 235 on their back side. Each individual electrode stripe 211, 221 is bonded to bond pads of a readout ASIC (Application Specific Integrated Circuit) 240 via bump balls 213 and interconnected in the readout ASIC 240 (cf. right-hand side of the Figure). Furthermore, external bond pads B are provided on the readout circuitry 240 for further connections.

It should be noted that, for reasons of clarity, in FIG. 2 and in the following Figures the reference signs 211, 221 etc. of the primary/supplementary electrodes are only drawn to a single, representative sub-unit, while “the electrode” actually is the set of all associated sub-units.

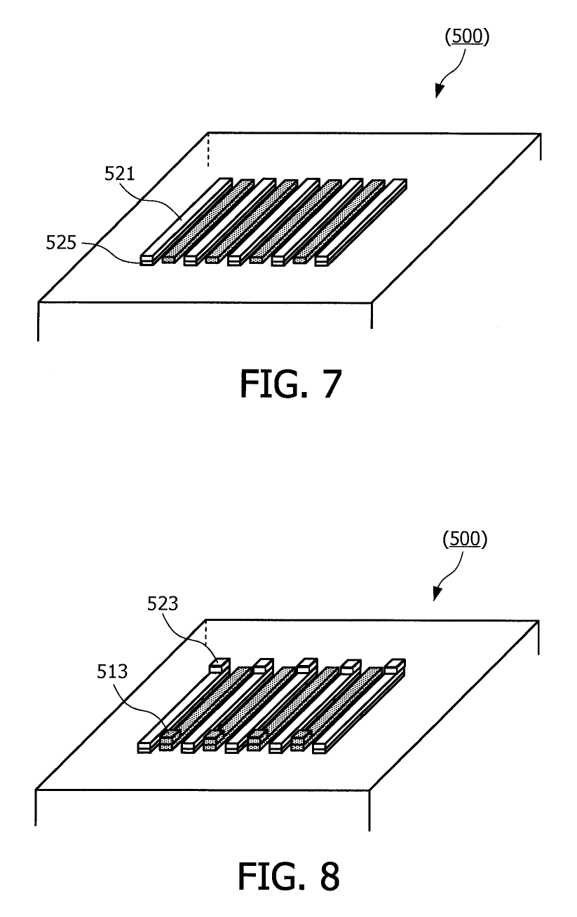

An alternative to the shown connection scheme would be a 2-layer metallization process on the converter material (one layer for connecting the electrode stripes and one layer for providing bond pads), which is described as a further embodiment of this invention further down with respect to FIGS. 5 to 9. It has the advantage that even thinner (and possibly smaller) stripes (with smaller distances between adjacent stripes) can be deposited on the direct conversion material. For this approach it has to be observed that Cd[Zn]Te only allows for relatively low processing temperatures ≦170° C.).

The embodiment of FIG. 2 means that for each stripe 211, 221 a bond pad is needed on the readout electronics ASIC 240.

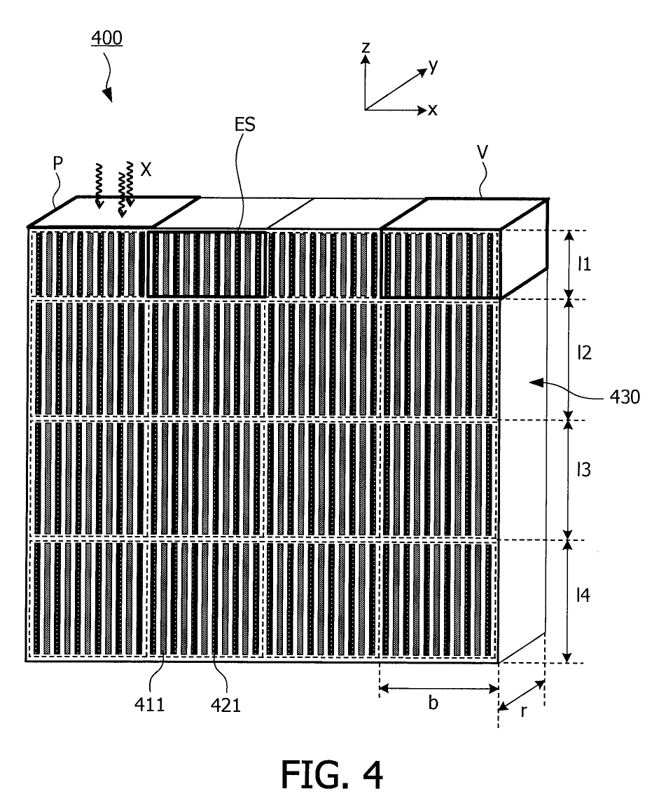

FIG. 3 illustrates the corresponding electrode geometry in a side view onto the electrode systems ES of a detector 300, the electrode systems ES comprising stripes of primary electrodes 311 and supplementary electrodes 321 (this detector may for example be used in horizontal illumination mode, in which the X-rays will be incident from the y-direction). Assuming a stripe width w of about 50 μm (and a length L of e.g. up to 1 mm) and a stripe distance d of about 40.9 μm, it is possible to deposit (in the required interleaved manner) six stripes of a non-collecting, supplementary electrode 321 and five stripes of the collecting, primary electrode 311, providing a pixel pitch of 1 mm (1 mm=11×50 μm+11×40.9 μm).

In such an assembly, each pixel (the pixels are defined by the areas covered by one electrode system ES each) is enclosed by the outmost stripes of the non-collecting, supplementary electrode 321 in order to provide some decoupling of neighboring pixels. It should be noted that the resulting pitch for bonding can be kept moderate (i.e. even larger than 40.9 μm+50 μm), since the bond pads for connecting the stripes of the collecting electrode can be staggered between different stripes, i.e. need not be on the same line as those for the non-collecting electrode (thus providing more space for each bond pad). To improve the bonding yield, more than one bond pad can be provided for each electrode stripe.

During operation, the non-collecting, supplementary electrode is on a lower potential than the collecting, primary electrode in order to change the electric field within the converter material bulk in such a way that charges are steered towards the collecting electrode stripes and driven away from the non-collecting electrode stripes.

Hence, it is preferable to have an isolating layer or passivation layer between the metal of the non-collecting, supplementary electrode and the bulk of the converter material, while the collecting electrode has to have sufficient (conductive) electrical contact with the bulk material so that charge generated within the converter material can be drained via the metal of the collecting electrode. A further advantage of the passivation layer is the possibility to short-circuit the individual stripes of the non-collecting electrode. Thus only one bump bond connection is necessary for the non-collecting electrode.

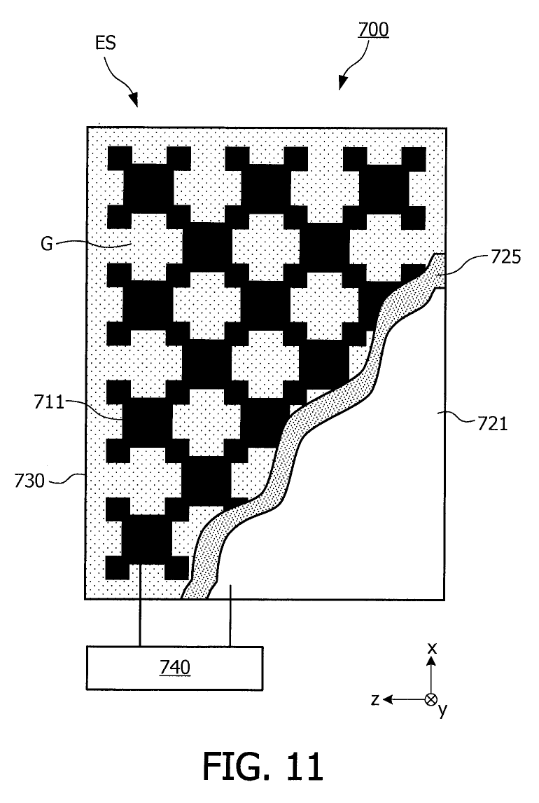

Another advantage of a passivation layer is that there are less geometrical constraints on the electrode design. For instance, a collecting electrode could have a chessboard pattern like that shown in FIG. 11.

FIG. 4 shows an exemplary arrangement of electrodes systems ES constituted by coplanar electrode grid structures defining—on a slab in a multi-slab edge-on assembly—voxels V of four pixels P, wherein each pixel P has four layers. The pixel size is here b (=1 mm)×“thickness r of the slab”. The layers have, in the direction of radiation incidence, increasing thicknesses of 11=500 μm, 12=800 μm, 13=800 μm, 14=900 μm.

With the dimensions of the detector 400 of FIG. 4, the maximum count rates in direct beam illumination have been simulated. For the two lower layers, the count rates are well below 10 Mcps (for 90 kVp, 400 mA, with beam shaper). So also in direct beam illumination it is still possible to estimate the energy of single photons, since material and readout electronics should be able to cope with count rates in this range. By accepting saturated layers, the incident spectrum can still be estimated even if top layers are in saturation and do not contribute to the data evaluation.

For higher tube voltages (e.g. 150 kVp) a different layer design would be required, e.g. with layer thicknesses of 2000 μm, 1000 μm, 500 μm, and 500 μm (in the direction of radiation incidence) to make sure that at least two layers see a count rate below 10 Mcps in the direct beam. An alternative would be to go for e.g. eight layers of 500 μm thickness each (assuming 1000 μm×1000 μm pixel size).

FIGS. 5 to 9 illustrate the consecutive manufacturing steps of a radiation detector 500 according to a further embodiment of the invention. In this design a two-layer structuring approach is used for defining the coplanar-grid structure of a single electrode system or pixel. This is done in such a way that a first layer defines the two groups of parallel stripes forming the collecting (primary) electrode and the non-collecting (supplementary) electrode, while the connections between the stripes of the same electrode is done in a second layer, which also provides the bond pads for bonding a readout ASIC.

Since now only the limitations of the photo-lithography process on the converter material have to be observed, it is possible to define even thinner stripes and smaller inter-stripe distances, e.g. 10 μm thin stripes with 5 μm distance, which further improves the resulting weighting potential and helps to achieve a further reduction of the required potential difference between collecting and non-collecting electrodes. With the mentioned dimensions, six non-collecting stripes and five collecting stripes could for example be arranged in a pixel of approximately 150×150 μm² size (i.e. the same number of collecting and non-collecting stripes would be achieved as in the above example of pixels with 1 mm pitch).

This opens up the possibility to define even smaller pixels than the mentioned 1×1 mm², which could be advantageous especially for X-ray detectors, which are mostly used for projection imaging and therefore require a pixel pitch of no larger than 150 μm×150 μm or even 100 μm×100 μm. Assuming 500 μm thick CdTe, which is readily available, it seems possible to devise a detector with such small pixels.

FIGS. 5 to 9 show a possible sequence of lithography steps for building a single pixel with a two-layer metal process on a direct converting material like Cd[Zn]Te.

FIG. 5 shows the deposition of a passivation 525 for the non-collecting electrode on the bulk of the converter element 530. For simplicity, the following Figures show just the surface of the converter element 530.

FIG. 6 shows the deposition of the collecting electrode stripes 511 directly on top of the bulk material 530.

FIG. 7 shows the deposition of the non-collecting electrode stripes 521 on top of the passivation stripes 525.

FIG. 8 shows the filling of vias 513 and 523 with metal (the dielectric material which embeds these vias is not shown).

FIG. 9 shows the deposition of connecting lines 512, 522 connecting the stripes 511 and 521, respectively. Moreover, it shows the deposition of the required two bond pads B_{c} and B_{nc} to which the readout circuitry can be connected in a next step (not shown).

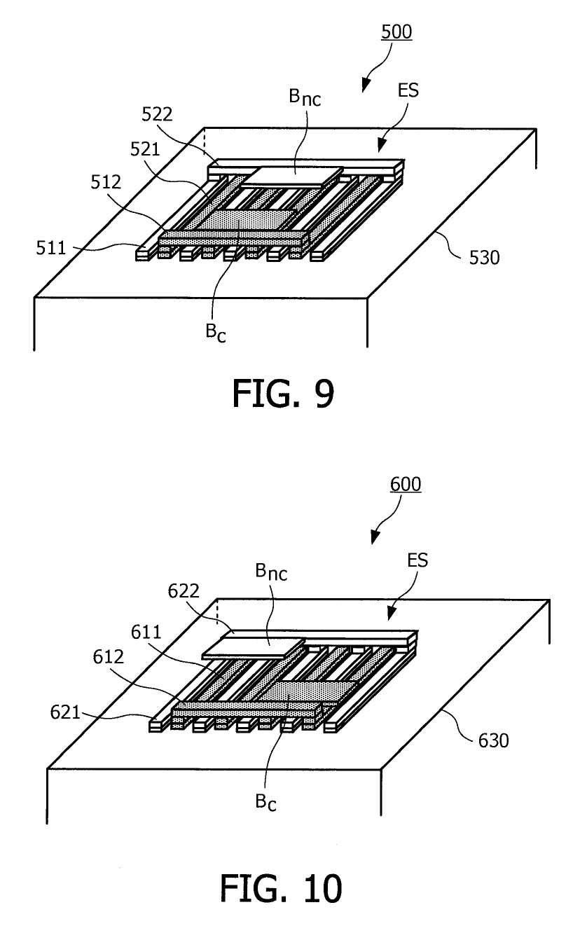

With a pixel pitch of 150 μm, the bond pad pitch will be in the (feasible) range of 75 μm. For 100 μm pitch pixels it might be required to use an alternative arrangement as shown in FIG. 10 for the radiation detector 600, in which the bond pads B_{c} and B_{nc} are located at diagonally opposite corners of the electrode system.

It was already mentioned that other electrode designs than stripe geometries are possible, too. Such designs may for example help that charges induced by holes generated in a converter element close to an electrode system are more symmetrically distributed between the primary and the supplementary electrode. Furthermore, alternative designs may allow for a lower voltage difference between the primary electrode and the supplementary electrode, thus reducing noise.

One example of an alternative electrode system ES for a detector 700 is shown in FIG. 11. In this design, the collecting primary electrode 711 extends in a chessboard pattern in an electrode area, which is represented in the Figure by black squares corresponding to metal pads and having a small overlap. Light squares correspond in the Figure to “gaps”, i.e. (internal) holes G in the electrode area. In these holes G, the surface of the converter block 730 is not covered by the primary electrode. The complementary non-collecting electrode 721 can be realized by a contiguous metal plane on a passivation layer 725, e.g. on a layer of benzocyclobutene (BCB) that is disposed above the surface of the primary electrode 711 and the converter block 730. However, in order to reduce capacitance and to minimize the risk for electrical breakthrough of the passivation layer, the non-collecting electrode can also feature holes. These are preferably located above the metalized area of the collecting primary electrode. The passivation layer 725 needs only one opening (not shown) for a via (and bond pad) of the collecting primary electrode 711, which is beneficial for detector production if a finite yield of the bump bonding process is taken into account. A distinct advantage of this solution is the fact that the grid structure not only focuses in one direction (e.g. perpendicular to the stripes of above embodiments), but in two directions. Thus, the pitch between squares can be larger than the corresponding stripe pitch.

The radiation detector 700 may comprise just the one single electrode system ES shown in FIG. 11, though it will preferably comprise a plurality of such electrode systems as in the designs described above.

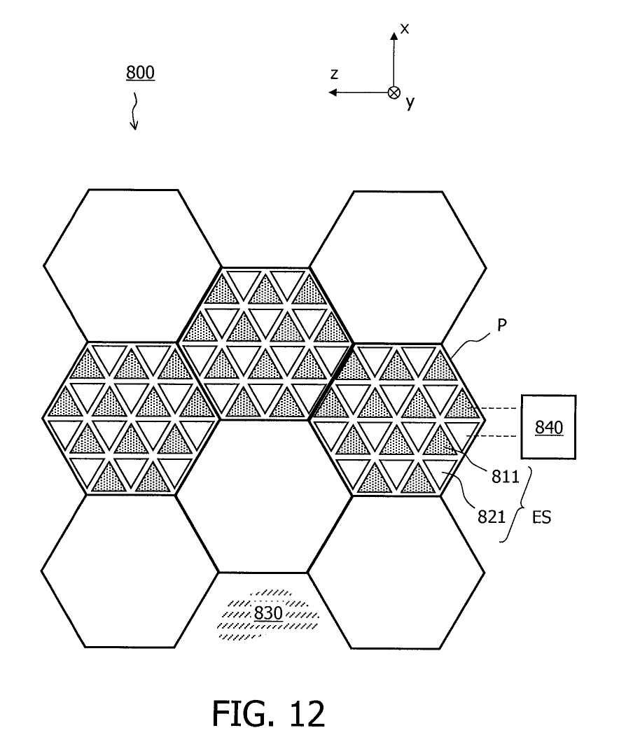

The radiation detector 800 shown in FIG. 12 is a further example in which a non-stripe electrode geometry is used. As in the above designs, the radiation detector 800 comprises a converter element 830 upon which a plurality of electrode systems ES is arranged in a regular pattern. In the shown example, each electrode system ES fills the hexagonal area of a pixel P, said hexagonal pixels P being assembled in a honeycomb tessellation.

Moreover, each electrode system ES comprises a primary electrode 811 and a supplementary electrode 821. The primary and the supplementary electrodes each consist of sub-units (sub-anodes) in the form of equilateral triangles that are arranged in an alternating manner to fill the hexagonal area of the electrode system ES. The radiation detector 800 thus achieves a higher degree of rotational symmetry than the stripe geometry of FIGS. 1-10.

The Figure only schematically indicates the connection of the primary electrodes 811 and the supplementary electrodes 821 of each pixel P to a readout circuitry 840. As in the previous embodiments, the readout electronics 840 measure the difference between the signals originating from the primary (collecting) and the supplementary (non-collecting) sub-anodes. The primary sub-anodes 811 are kept at e.g. GND potential, while the supplementary sub-anodes 821 are kept at a negative potential (usually not as low as that of the cathode) in order to make sure that the electric field directs electrons from almost the whole volume of the converter element to the collecting sub-anodes.

The electrode systems ES in the radiation detector 800 are one example of a more general design principle that is characterized by the fact that, in each direction within the area of an electrode system ES (xy-plane), the primary electrode and/or the supplementary electrode are once or (preferably) multiple times interrupted. In particular, the radiation detector 800 is an example in which both the primary electrode 811 and the supplementary electrode 821 have multiple interruptions in each direction. The radiation detector 700 of FIG. 11, on the contrary, is an example in which only the supplementary electrode 721 is repetitively interrupted in each direction.

A patterned electrode structure with the aforementioned features may be advantageous compared to a grid structure, as capacitively induced charges are distributed more homogeneously across the collecting and the non-collecting sub-anodes. This implies that the difference between the signals of collecting and non-collecting sub-anodes is minimized (ideally to zero), and the photo peak will be more sharpened. Furthermore, a hexagonal pixel shape may reduce charge sharing between neighbored pixels, thus reducing the low energy tailing.

The collecting triangular sub-units of the primary electrode 811 may be connected to each other either using a 3-metal-layer process or by interconnecting them on the readout ASIC, which is bonded to the material as already described above.

Since the vertices of the equilateral triangles, which belong to collecting and non-collecting sub-anodes, are very close to each other, the design shown in FIG. 12 may result in very high electric fields in the neighborhood of the vertices. This can be mitigated by using rounded vertices (not shown) at the cost of a slightly increased area without metallization. Assuming an area of 1 mm² for the hexagonal pixel P, the triangle area would be roughly 1 mm²/24=41700 μm², and the triangle side would be 219.3 μm with gap widths in the range of 20 μm.

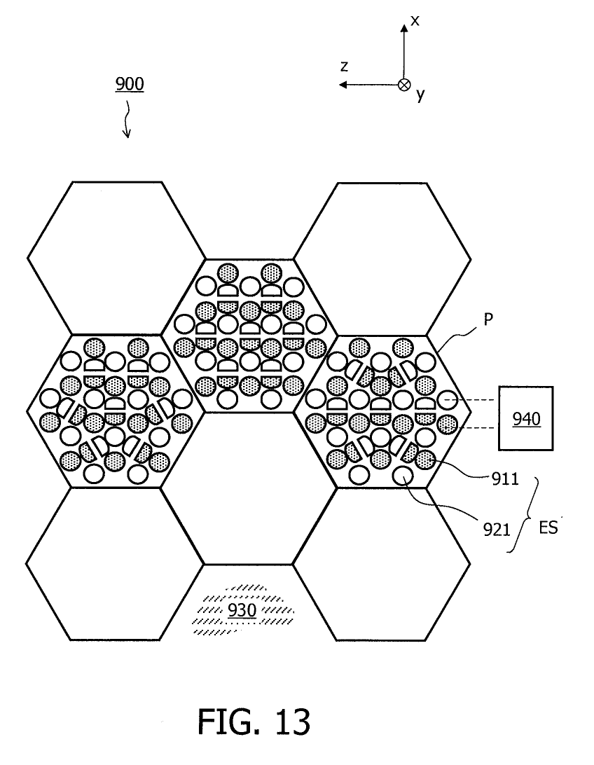

In an approach to avoid high electrical field strengths, only sub-units in the form of circles may be used. As this may result in some disturbance of the symmetry, sub-units in the form of circles and half circles might be used, where the half circles are e.g. arranged randomly, since they slightly disturb the hexagonal symmetry. Such an embodiment is realized in the radiation detector 900 shown in FIG. 13. This detector is identical to the detector 800 inasmuch as it comprises an arrangement of hexagonal electrode systems ES (constituting pixels P) on a converter element 930. The sub-units of the primary electrode 911 and the supplementary electrode 921 have however the form of circles and randomly distributed half circles.

Though a plurality of electrode systems ES is shown in FIGS. 12 and 13, the respective design of the electrode systems can also be applied in radiation detectors having just a single electrode system.

The described detector designs are particularly suited for photon-counting Spectral CT. The performance of a photon-counting based energy-resolving Spectral CT system gets better, the smaller the low-energy tail in the response of the detector to each of the energies in the medically relevant energy range between 20 and 140 keV is. To achieve this, it is proposed here to use coplanar electrode grids for defining the pixelated anodes. The coplanar electrode approach requires, for each pixel, forming the (analog) difference between the signals generated by the collecting and the non-collecting electrode.

Furthermore, the invention can be applied in all X-ray detection systems that use energy-resolving counting detectors, where a good energy-resolution is intended, especially in medical imaging and medical Computed Tomography.

Finally it is pointed out that in the present application the term “comprising” does not exclude other elements or steps, that “a” or “an” does not exclude a plurality, and that a single processor or other unit may fulfill the functions of several means. The invention resides in each and every novel characteristic feature and each and every combination of characteristic features. Moreover, reference signs in the claims shall not be construed as limiting their scope.

1. A radiation detector, comprising:
a) a converter element for converting incident radiation (X) into electrical signals;
b) a plurality of electrode systems (ES) that are arranged on the converter element, each electrode system comprising a primary electrode and, electrically isolated therefrom, a supplementary electrode;
c) a readout circuitry that is individually connected to the primary electrodes and supplementary electrodes for applying electrical potentials to them.

2. A method for manufacturing a radiation detector, said method comprising the following steps:
a) disposing a plurality of electrode systems (ES) on a converter element such that each electrode system comprises a primary electrode and, electrically isolated therefrom, a supplementary electrode;
b) individually connecting a readout circuitry to the primary electrodes and the supplementary electrodes.

3. The radiation detector according to claim 1,
wherein the primary electrode and the supplementary electrode of at least one electrode system (ES) are arranged in a common planar layer with a thickness of e.g. less than about 10 μm.

4. The radiation detector according to claim 1,
wherein the electrode systems (ES) are arranged in a two-dimensional hexagonal pattern on the converter element.

5. The radiation detector according to claim 1,
wherein at least one primary electrode and/or supplementary electrode comprises a plurality of parallel stripes.

6. The radiation detector according to claim 5,
wherein parallel stripes of such a primary electrode and such a supplementary electrode are arranged in an alternating manner.

7. The radiation detector according to claim 1,
wherein at least one primary electrode and/or supplementary electrode consists of plurality of sub-units arranged in a common plane.

8. The radiation detector according to claim 7,
wherein each sub-unit carries a contact terminal that is disposed above said common plane.

9. The radiation detector according to claim 7,
wherein sub-units are electrically coupled to each other by a connection element extending at a distance from said common plane of the sub-units.

10. The radiation detector according to claim 1,
wherein an isolating layer is disposed between the converter element and at least one supplementary electrode.

11. The radiation detector according to claim 1,
wherein at least one primary electrode and/or supplementary electrode extends along two opposite sides of the corresponding electrode system.

12. The method according to claim 2,
wherein the disposition of at least one primary electrode and/or supplementary electrode comprises the following steps:
a1) disposing a plurality of sub-units in a common plane on the converter element;
a2) disposing contact terminals on the sub-units;
a3) disposing a connection element on the contact terminals such that the sub-units are electrically coupled.

13. A radiation detector, according to claim 1, comprising:
a) a converter element for converting incident radiation into electrical signals;
b) an electrode system (ES) that is arranged on the converter element and comprises a primary electrode and, electrically isolated therefrom, a supplementary electrode, wherein the primary electrode comprises an electrode area with at least one hole (G);
c) a readout circuitry that is connected to the primary electrode and the supplementary electrode for applying electrical potentials to them.

14. A radiation detector, according to claim 13, comprising:
a) a converter element for converting incident radiation into electrical signals;
b) an electrode system (ES) that is arranged on the converter element and comprises a primary electrode and, electrically isolated therefrom, a supplementary electrode, wherein in each direction within the area of the electrode system the primary electrode and/or the supplementary electrode is interrupted;
c) a readout circuitry that is connected to the primary electrode and the supplementary electrode for applying electrical potentials to them.

15. The method of claim 2,
wherein the primary electrode and the supplementary electrode of at least one electrode system (ES) are arranged in a common planar layer with a thickness of e.g. less than about 10 μm.

16. The method of claim 2,
wherein the electrode systems (ES) are arranged in a two-dimensional hexagonal pattern on the converter element.

17. The method of claim 2,
wherein at least one primary electrode and/or supplementary electrode consists of plurality of sub-units arranged in a common plane.

18. The method of claim 2,
wherein an isolating layer is disposed between the converter element and at least one supplementary electrode.
